(19) United States
(12) Patent Application Publication
(10) Pub. No.: US 2025/0113713 A1
(43) Pub. Date: Apr. 3, 2025

(54) DISPLAY SUBSTRATE, MANUFACTURING METHOD THEREOF, DISPLAY PANEL AND DISPLAY APPARATUS

(71) Applicant: BOE TECHNOLOGY GROUP CO., LTD., Beijing (CN)

(72) Inventor: Wenxiu ZHU, Beijing (CN)

(21) Appl. No.: 18/833,110

(22) PCT Filed: Sep. 26, 2023
(86) PCT No.: PCT/CN2023/121602

§ 371 Date: Jul. 25, 2024

(30) Foreign Application Priority Data
Nov. 16, 2022 (CN) 202211438063.6

(51) Int. Cl. H10K 59/131; H10K 59/121; H10K 59/122; H10K 59/80; H10K 59/88

(52) U.S. Cl. CPC H10K 59/131; H10K 59/121; H10K 59/122; H10K 59/80515; H10K 59/88

(57) ABSTRACT

A display substrate includes a pixel driver circuit and a plurality of first electrodes on the pixel driver circuit. The pixel driver circuit includes a base and a plurality of first signal wires; orthographic projections of the first signal wires on the base are partially overlapped with orthographic projections of the first electrodes on the base; the first electrodes each have a strip shape; the extending direction of the first signal wires forms acute angles with a length direction and a width direction of the strip, respectively; and the display substrate further includes an auxiliary leveling structure on a side of the first signal wires away from the base and a side of the first electrodes close to the base, and an orthographic projection of the auxiliary leveling structure on the base covers at least the orthographic projections of the first electrodes on the base.

### TECHNICAL FIELD

Embodiments of the present disclosure belong to the field of display technology, and specifically relate to a display substrate, a manufacturing method thereof, a display panel and a display apparatus.

### BACKGROUND

Due to the properties of self-luminescence, high brightness, wide viewing angle, high contrast, flexibility, and low energy consumption, the organic light-emitting diode (OLED) display apparatus has gained wide attention and become a new generation display mode, and begun to gradually replace the traditional liquid crystal display apparatus to be widely used in mobile phone screens, computer monitors, full color televisions and the like. In the existing art, OLED display apparatuses may be classified into a top emitting type and a bottom emitting type based on their emission modes.

### SUMMARY

Embodiments of the present disclosure provide a display substrate, a manufacturing method thereof, a display panel and a display apparatus.

In a first aspect, an embodiment of the present disclosure provides a display substrate, including a pixel driver circuit and a plurality of first electrodes on the pixel driver circuit, wherein
the pixel driver circuit includes a base, and a plurality of first signal wires in a same layer on the base; the plurality of first signal wires have the same extending direction;
the first electrodes and the first signal wires are in different layers;
orthographic projections of the first signal wires on the base are partially overlapped with orthographic projections of the first electrodes on the base;
the first electrodes each have a strip shape, and the plurality of first electrodes are arranged in an array along a length direction and a width direction of the strip shape;
the extending direction of the first signal wires forms acute angles greater than 0° and smaller than 90° with the length direction and the width direction of the strip, respectively; and
the display substrate further includes an auxiliary leveling structure on a side of the first signal wires away from the base and a side of the first electrodes close to the base, and an orthographic projection of the auxiliary leveling structure on the base covers at least the orthographic projections of the first electrodes on the base; and
the auxiliary leveling structure enables a layer of the first electrodes flat.

In some embodiments, the auxiliary leveling structure includes a plurality of planarization layers having orthographic projections on the base covering an orthographic projection of the pixel driver circuit on the base;
the plurality of planarization layers are sequentially stacked on a side of the first signal wires away from the base, and a surface, close to the first electrodes, of one of the planarization layers closest to the first electrodes is planar; and each first electrode is a planar layer.

In some embodiments, the auxiliary leveling structure further includes a dummy structure between any two adjacent planarization layers and distributed at least in a region of an orthographic projection of a corresponding first electrode on the base; and
an orthographic projection of the dummy structure on the base is not overlapped with the orthographic projections of the first signal wires on the base, and forms a complementary pattern with the orthographic projections of the first signal wires on the base.

In some embodiments, the auxiliary leveling structure further includes a dummy structure in the same layer as the first signal wires and distributed at least in a region of an orthographic projection of a corresponding first electrode on the base; and
an orthographic projection of the dummy structure on the base is not overlapped with the orthographic projections of the first signal wires on the base, and forms a complementary pattern with the orthographic projections of the first signal wires on the base.

In some embodiments, the auxiliary leveling structure further includes a plurality of dummy structures in the same layer as the first signal wires and distributed at least in a region of an orthographic projection of a corresponding first electrode on the base; and
orthographic projections of the dummy structures on the base are not overlapped with the orthographic projections of the first signal wires on the base, and adjacent first signal wires, and each dummy structure and an adjacent first signal wire, are equally spaced.

In some embodiments, the auxiliary leveling structure further includes a plurality of dummy structures between any two adjacent planarization layers and distributed at least in a region of an orthographic projection of a corresponding first electrode on the base; and
orthographic projections of the dummy structures on the base are not overlapped with the orthographic projections of the first signal wires on the base, and the orthographic projections of adjacent first signal wires on the base, the orthographic projections of each dummy structure and an adjacent first signal wire on the base, and the orthographic projections of adjacent dummy structures on the base, are equally spaced.

In some embodiments, the plurality of first signal wires are parallel to each other;
the orthographic projections of adjacent first signal wires on the base, the orthographic projections of each dummy structure and an adjacent first signal wire on the base, and the orthographic projections of adjacent dummy structures on the base, are spaced by a distance less than or equal to a minimum line width of the first signal wires; and
a width of each dummy structure in an arrangement direction of the plurality of first signal wires is less than or equal to the minimum line width of the first signal wires.

In some embodiments, the auxiliary leveling structure includes a plurality of dummy structures and a plurality of planarization layers having orthographic projections on the base covering an orthographic projection of the pixel driver circuit on the base;
the plurality of dummy structures are in the same layer as the first signal wires; and the plurality of dummy structures are distributed at least in a region of an orthographic projection of a corresponding first electrode on the base;
orthographic projections of the dummy structures on the base are not overlapped with the orthographic projections of the first signal wires on the base, and adjacent first signal wires, and each dummy structure and an adjacent first signal wire, are equally spaced; and
the plurality of planarization layers are sequentially stacked on a side of the first signal wires away from the base, and a surface, close to the first electrodes, of one of the planarization layers closest to the first electrodes is a uniformly concaved surface.

In some embodiments, the auxiliary leveling structure includes a plurality of dummy structures and a plurality of planarization layers having orthographic projections on the base covering an orthographic projection of the pixel driver circuit on the base;
the plurality of dummy structures are between any two adjacent planarization layers; and the plurality of dummy structures are distributed at least in a region of an orthographic projection of a corresponding first electrode on the base;
orthographic projections of the dummy structures on the base are not overlapped with the orthographic projections of the first signal wires on the base, and the orthographic projections of adjacent first signal wires on the base, the orthographic projections of each dummy structure and an adjacent first signal wire on the base, and the orthographic projections of adjacent dummy structures on the base, are equally spaced; and
the plurality of planarization layers are sequentially stacked on a side of the first signal wires away from the base, and a surface, close to the first electrodes, of one of the planarization layers closest to the first electrodes is a uniformly concaved surface.

In some embodiments, each first electrode is a uniformly concaved layer.

In some embodiments, the orthographic projections of adjacent first signal wires on the base, the orthographic projections of each dummy structure and an adjacent first signal wire on the base, and the orthographic projections of adjacent dummy structures on the base, are spaced by a distance equal to an average line width of the plurality of first signal wires, respectively; and
a width of each dummy structure in an arrangement direction of the plurality of first signal wires is equal to the average line width of the plurality of first signal wires.

In some embodiments, one of the planarization layers closest to the first signal wires has a larger thickness than a thickness of the first signal wires.

In some embodiments, each dummy structure has a thickness less than or equal to a thickness of the first signal wires.

In some embodiments, each dummy structure has a thickness equal to a thickness of the first signal wires.

In some embodiments, each dummy structure is made of an insulating material or a conductive material; and
the conductive material includes the same conductive material as the first signal wires.

In some embodiments, the dummy structure is made of an insulating material.

In some embodiments, the pixel driver circuit further includes a plurality of second signal wires in a same layer on the base; the plurality of second signal wires have the same extending direction;
the extending direction of the second signal wires forms acute angles greater than 0° and smaller than 90° with a length direction and a width direction of the strip, respectively;
the second signal wires are on a side of the first signal wires close to the base; and
an insulation layer is further provided between the second signal wires and the first signal wires.

In some embodiments, the extending direction of the first signal wires forms angles of 40° to 50° with the length direction and the width direction of the strip, respectively; and
the extending direction of the second signal wires forms angles of 40° to 50° with the length direction and the width direction of the strip, respectively.

In some embodiments, the first electrodes each have a shape including any one of rectangle, diamond, ellipse, or trapezoid.

In some embodiments, the first signal wires include data lines or power lines or gate lines; and
the second signal wires include gate lines or data lines or power lines.

In some embodiments, each dummy structure is made of a conductive material and connected to a first potential signal or a second potential signal;
the first potential signal is greater than the second potential signal; the second potential signal is greater than or equal to a ground potential; and
the first potential signal includes a potential of a power line.

In a second aspect, an embodiment of the present disclosure further provides a display panel, including the display substrate as described above.

In some embodiments, the display panel further includes a pixel defining layer, an emission functional layer, and a second electrode; wherein
the pixel defining layer, the emission functional layer and the second electrode are sequentially stacked on a side of the first electrodes in the display substrate away from the pixel driver circuit; and
the pixel defining layer is provided with a plurality of openings from which the first electrodes are partially exposed, and orthographic projections of the emission functional layer and the second electrode on the pixel driver circuit cover at least orthographic projections of the openings on the pixel driver circuit.

In a third aspect, an embodiment of the present disclosure further provides a display apparatus, including the display panel as described above.

In a fourth aspect, an embodiment of the present disclosure further provides a method for manufacturing a display substrate, including: manufacturing a pixel driver circuit; and
manufacturing a plurality of first electrodes on the pixel driver circuit; wherein
manufacturing the pixel driver circuit includes manufacturing a plurality of first signal wires on a base; wherein
the plurality of first signal wires have the same extending direction;
orthographic projections of the first signal wires on the base are partially overlapped with orthographic projections of the first electrodes on the base;
the first electrodes each have a strip shape, and the plurality of first electrodes are arranged in an array along a length direction and a width direction of the strip shape; and
the extending direction of the first signal wires forms acute angles greater than 0° and smaller than 90° with the length direction and the width direction of the strip, respectively; and
after manufacturing the pixel driver circuit and before manufacturing the first electrodes, the method further includes: manufacturing an auxiliary leveling structure, wherein an orthographic projection of the auxiliary leveling structure on the base covers at least the orthographic projections of the first electrodes on the base.

In some embodiments, manufacturing the auxiliary leveling structure includes: manufacturing a plurality of planarization layers sequentially through a coating process.

In some embodiments, manufacturing the auxiliary leveling structure further includes: manufacturing a dummy structure through a patterning process.

In some embodiments, in manufacturing of any two adjacent planarization layers, the dummy structure is manufactured after one of the planarization layers is manufactured and before the other is manufactured.

In some embodiments, the dummy structure and the first signal wires are manufactured in a single patterning process.

In some embodiments, the first signal wires and the dummy structure are sequentially manufactured in a single patterning process.

### BRIEF DESCRIPTION OF DRAWINGS

Accompanying drawings are provided for further understanding of the embodiments of the present disclosure and constitute a part of the specification. Hereinafter, these drawings are intended to explain the present disclosure together with the following embodiments, but should not be considered as a limitation to the present disclosure. The above and other features and advantages will become more apparent to those skilled in the art by describing in detail exemplary embodiments thereof with reference to the attached drawings, in which:

FIG. 1 is a schematic top view illustrating pixel arrangement in an OLED display panel in the existing art.

FIG. 2 is a schematic top view illustrating arrangement of subpixels and signal wires closest to the subpixels in an OLED display panel in the existing art.

FIG. 3 is a schematic sectional view of the OLED display panel in FIG. 2 taken along line AA′.

FIG. 4 is a schematic top view of a plurality of signal wires overlapped with a subpixel and arranged relatively uniformly in a distribution region of the subpixel.

FIG. 5 is a top view illustrating a structure of a display substrate according to an embodiment of the present disclosure.

FIG. 6 is a sectional view illustrating a structure of the display substrate in FIG. 5 taken along line BB′.

FIG. 7 is a sectional view illustrating another structure of the display substrate in FIG. 5 taken along line BB′.

FIG. 8 is a sectional view illustrating yet another structure of the display substrate in FIG. 5 taken along line BB′.

FIG. 9 is a sectional view illustrating yet another structure of the display substrate in FIG. 5 taken along line BB′.

FIG. 10 is a sectional view illustrating yet another structure of the display substrate in FIG. 5 taken along line BB′.

FIG. 11 is a sectional view illustrating yet another structure of the display substrate in FIG. 5 taken along line BB′.

FIG. 12 is a sectional view illustrating yet another structure of the display substrate in FIG. 5 taken along line BB′.

FIG. 13a is a top view illustrating another structure of a display substrate according to an embodiment of the present disclosure.

FIG. 13b is a sectional view illustrating a structure of the display substrate in FIG. 13a taken along line CC′.

FIG. 14 is a sectional view illustrating a structure of a display panel according to an embodiment of the present disclosure.

### DETAIL DESCRIPTION OF EMBODIMENTS

To make those skilled in the art better understand the technical solutions in the embodiments of the present disclosure, the display substrate, the manufacturing method thereof, the display panel and the display apparatus provided in the embodiments of the present disclosure will be described in further detail below with reference to the accompanying drawings and specific implementations.

Embodiments of the present disclosure will be described more sufficiently below with reference to the accompanying drawings, which may be embodied in different forms and should not be construed as being limited to the embodiments set forth herein. Rather, these embodiments are provided so that the present disclosure will be thorough and complete, and will fully convey the scope of the present disclosure to those skilled in the art.

The embodiments of the present disclosure are not limited to the embodiments shown in the drawings, but further include modifications of configurations formed based on a manufacturing process. Thus, the regions illustrated in the figures have schematic properties, and the shapes of the regions shown in the figures illustrate specific shapes of regions, but are not intended to be limitative.

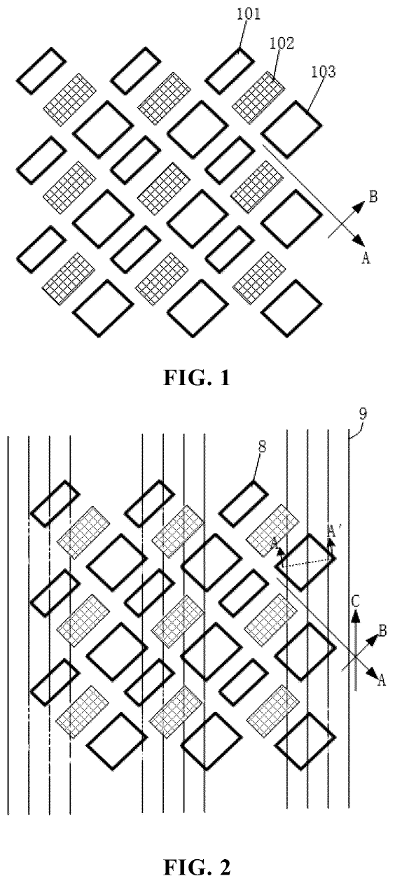

Referring to FIG. 1, a schematic top view illustrating pixel arrangement in an organic light-emitting diode (OLED) display panel in the existing art is shown. The OLED display panel includes a plurality of pixels each including a red subpixel 101, a green subpixel 102 and a blue subpixel 103 arranged in a first direction A. Each subpixel has a strip shape, and a length extending along a second direction B. The first direction A and the second direction B form an angle greater than 0° and less than or equal to 90°.

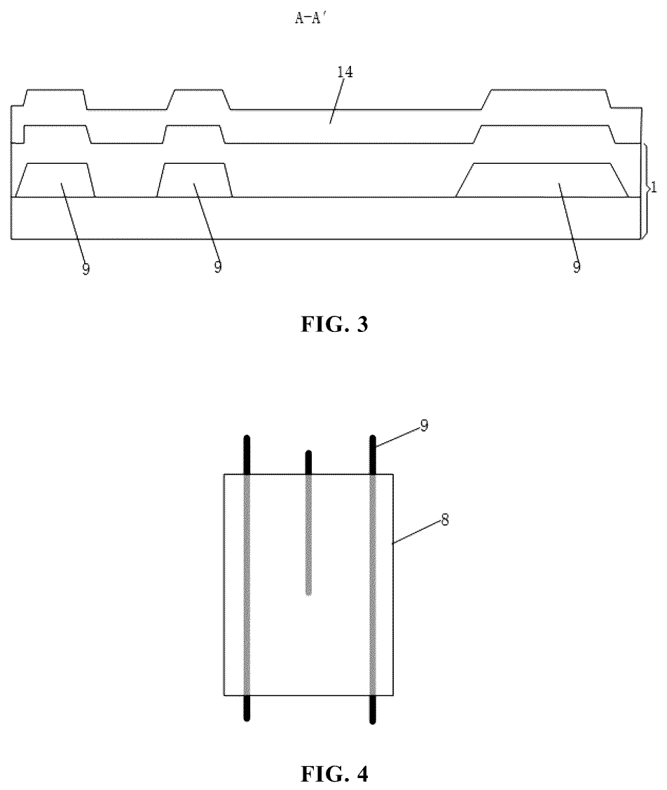

Referring to FIG. 2, a schematic top view illustrating arrangement of subpixels and signal wires closest to the subpixels in an OLED display panel in the existing art is shown. In the OLED display panel, each subpixel includes a light-emitting device 8 and a pixel driver circuit 1. The light-emitting device 8 is located on the pixel driver circuit 1, and the pixel driver circuit 1 includes multiple layers of signal wires 9. One layer of signal wires 9 closest to each light-emitting device 8 includes a plurality of signal wires 9 extending in parallel along a third direction C (i.e., a longitudinal direction) which forms an angle of 45° with the first direction A in which the light-emitting device 8 is arranged. Referring to FIG. 3, a schematic sectional view of the OLED display panel in FIG. 2 taken along line AA′ is shown. As can be seen from FIG. 3, no matter what symmetrical routing manner is adopted for the plurality of signal wires 9 extending along the third direction, it is impossible to satisfy a relatively uniform arrangement of the signal wires 9 overlapped with the light-emitting device 8 in a distribution region of the light-emitting device 8 (see FIG. 4, which is a schematic top view of a plurality of signal wires overlapped with a light-emitting device and arranged relatively uniformly in a distribution region of the light-emitting device), the non-uniform arrangement of the signal wires 9 in the distribution region of the light-emitting device 8 causes an uneven surface of the pixel driver circuit 1 corresponding to the distribution region of the light-emitting device 8, such as uneven segment differences at different positions on the surface of the pixel driver circuit 1 in the distribution region of each light-emitting device 8, which may cause a layer of an electrode 14 (i.e., an anode of a light-emitting device such as an OLED element) in the light-emitting device 8 that directly contacts the surface of the pixel driver circuit 1 to be uneven, leading to an asymmetrical viewing angle of the OLED display panel. That is, when viewed from a relatively large viewing angle, the OLED display panel shows differences in the display color or display brightness, such as a reddish or greenish display color, or brighter or darker display brightness.

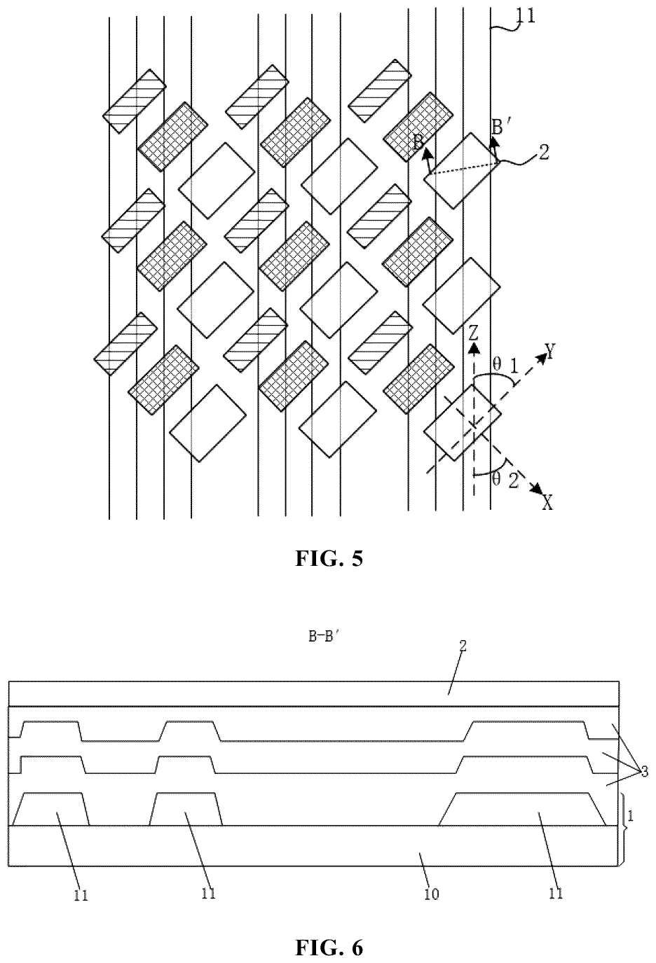

In view of the above problems, in a first aspect, an embodiment of the present disclosure provides a display substrate. Referring to FIG. 5, which is a top view illustrating a structure of a display substrate according to an embodiment of the present disclosure, the display substrate includes: a pixel driver circuit 1 and a plurality of first electrodes 2 on the pixel driver circuit 1. The pixel driver circuit 1 includes a base 10, and a plurality of first signal wires 11 in a same layer on the base 10. The plurality of first signal wires 11 have the same extending direction. The first electrodes 2 and the first signal wires 11 are in different layers. Orthographic projections of the first signal wires 11 on the base are partially overlapped with orthographic projections of the first electrodes 2 on the base 10. The first electrodes 2 each have a strip shape, and the plurality of first electrodes 2 are arranged in an array along a length direction Y and a width direction X of the strip shape. The extending direction Z of the first signal wires 11 forms acute angles θ1 and θ2 greater than 0° and smaller than 90° with the length direction Y and the width direction X of the strip, respectively. The display substrate further includes an auxiliary leveling structure on a side of the first signal wires 11 away from the base 10 and a side of the first electrodes 2 close to the base 10, and an orthographic projection of the auxiliary leveling structure on the base 10 covers at least the orthographic projections of the first electrodes 2 on the base 10. The auxiliary leveling structure enables a layer of the first electrodes 2 flat.

Each first electrode 2 serves as an anode of a corresponding subpixel. Each subpixel includes an OLED element, an LED element, a Mini LED element, or a Micro LED element.

In some embodiments, the first electrodes 2 each have a shape including any one of rectangle, diamond, ellipse, or trapezoid.

In some embodiments, the trapezoid has at least a long base with a length greater than a height of the trapezoid, so that the trapezoid is elongated as a whole; and a length direction of the trapezoid is an extending direction of the base of the trapezoid, while a width direction of the trapezoid is a height direction of the trapezoid.

In some embodiments, the extending direction Z of the first signal wires 11 forms angles of 40° to 50° with the length direction Y and the width direction X of the strip, respectively.

In some embodiments, the extending direction Z of the first signal wires 11 forms an angle of 45° with the length direction Y and the width direction X of the strip, respectively.

In this embodiment, by forming acute angles θ1 and θ2 greater than 0° and smaller than 90° between the extending direction Z of the first signal wires 11 and the length direction Y and the width direction X of the strip, respectively, especially by forming angles of 45° between the extending direction Z of the first signal wires 11 and the length direction Y and the width direction X of the strip, respectively, an aperture ratio of the display panel employing the display substrate can be increased on the one hand, and on the other hand, a visual effect with an oblique step feeling of the display panel employing the display substrate can be enhanced.

In some embodiments, the plurality of first signal wires 11 may be signal wires in any layer in the pixel driver circuit 1. In this embodiment, the layer where the plurality of first signal wires 11 are located is a conductive layer closest to the first electrodes 2 in the pixel driver circuit 1, that is, the first signal wires 11 are a layer of signal wires closest to the first electrodes 2 in the pixel driver circuit 1. By providing the auxiliary leveling structure between the layer where the first signal wires 11 are located and the layer where the first electrodes 2 are located, and making the orthographic projection of the auxiliary leveling structure on the base 10 cover at least the orthographic projections of the first electrodes 2 on the base 10, a surface layer of the pixel driver circuit 1 corresponding to the region where the first electrodes 2 are located can be filled and leveled, thereby making the layer of the first electrodes 2, which is formed in the region of the leveled surface layer, be flat or tend to be flat. Therefore, the problem of asymmetrical viewing angle of the display panel employing the display substrate can be alleviated or eliminated, and the display effect of the display panel employing the display substrate can be improved.

In some embodiments, the first signal wires 11 include data lines or power lines or gate lines.

In some embodiments, referring to FIG. 6, a sectional view illustrating a structure of the display substrate in FIG. 5 taken along line BB′ is shown. The auxiliary leveling structure includes a plurality of planarization layers 3 having orthographic projections on the base 10 covering an orthographic projection of the pixel driver circuit 1 on the base 10. The plurality of planarization layers 3 are sequentially stacked on a side of the first signal wires 11 away from the base 10, and a surface, close to the first electrodes 2, of one of the planarization layers 3 closest to the first electrodes 2 is planar. each first electrode 2 is a planar layer.

The planarization layers 3 may be made of an organic polymer material, such as polyimide (PI), polyethylene (PE), polycarbonate (PC), or the like. The planarization layers 3 made of the organic polymer material may be used for manufacturing a thicker layer, so as to facilitate leveling the surface segment difference caused by the first signal wires 11, make the layer of the first electrodes 2 formed thereon flat, and finally alleviate or eliminate the problem of asymmetrical viewing angle of the display panel employing the display substrate.

In some embodiments, three planarization layers 3 are provided. In some embodiments, one of the planarization layers 3 closest to the first signal wires 11 has a larger thickness than a thickness of the first signal wires 11, which is beneficial to reducing the layer segment difference caused by the first signal wires 11, and by providing the subsequent planarization layers 3, the layer segment difference caused by the first signal wires 11 can be leveled, so that a surface, close to the first electrodes 2, of one of the planarization layers 3 closest to the first electrodes 2 is planar, and therefore, the layer of the first electrodes 2 formed thereon are made flat.

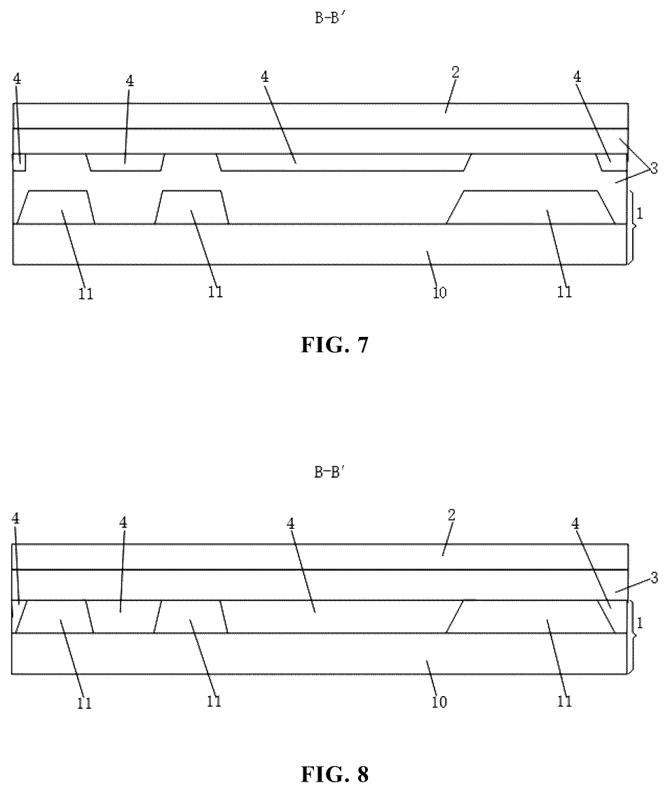

In some embodiments, referring to FIG. 7, a sectional view illustrating another structure of the display substrate in FIG. 5 taken along line BB′ is shown. The auxiliary leveling structure further includes a dummy structure 4 between any two adjacent planarization layers 3 and distributed at least in a region of an orthographic projection of a corresponding first electrode 2 on the base 10. An orthographic projection of the dummy structure 4 on the base 10 is not overlapped with the orthographic projections of the first signal wires 11 on the base 10, and forms a complementary pattern with the orthographic projections of the first signal wires 11 on the base 10.

With the orthographic projections of the dummy structure 4 and the first signal wires 11 on the base 10 forming complementary patterns, the layer segment difference caused by the first signal wires 11 can be reduced or leveled, so that a surface, close to the first electrodes 2, of one of the planarization layers 3 closest to the first electrodes 2 is planar, and therefore, the layer of the first electrodes 2 formed thereon are made flat.

In some embodiments, referring to FIG. 7, each dummy structure 4 has a thickness less than or equal to a thickness of the first signal wires 11. Therefore, the layer segment difference caused by the first signal wires 11 can be reduced or leveled.

In some embodiments, referring to FIG. 7, each dummy structure 4 is made of an insulating material or a conductive material; and the conductive material includes the same conductive material as the first signal wires 11. The insulating material is an inorganic insulating material such as silicon nitride, silicon oxide or silicon oxynitride, or the like, and the dummy structures 4 of the material may be manufactured through a patterning process (including the process steps of film formation, exposure, development, dry etching, and the like). The insulating material may be an organic insulating material, and the dummy structure 4 of the organic insulating material may be manufactured through an exposure process (including the process steps of film coating, exposure, development and the like). However, the insulating material is not limited to the above inorganic or organic insulating material. The conductive material may be, for example, copper, aluminum, or the like, but is not limited thereto.

In some embodiments, each dummy structure 4 is made of a conductive material and connected to a first potential signal or a second potential signal; the first potential signal is greater than the second potential signal; the second potential signal is greater than or equal to a ground potential; and the first potential signal includes a potential of a power line.

In some embodiments, referring to FIG. 8, a sectional view illustrating yet another structure of the display substrate in FIG. 5 taken along line BB′ is shown. The auxiliary leveling structure further includes a dummy structure 4 in the same layer as the first signal wires 11 and distributed at least in a region of an orthographic projection of a corresponding first electrode 2 on the base 10. An orthographic projection of the dummy structure 4 on the base 10 is not overlapped with the orthographic projections of the first signal wires 11 on the base 10, and forms a complementary pattern with the orthographic projections of the first signal wires 11 on the base 10.

With the orthographic projections of the dummy structure 4 and the first signal wires 11 on the base 10 forming complementary patterns, the layer segment difference caused by the first signal wires 11 can be reduced or leveled, so that a surface, close to the first electrodes 2, of one of the planarization layers 3 closest to the first electrodes 2 is planar, and therefore, the layer of the first electrodes 2 formed thereon are made flat.

In some embodiments, referring to FIG. 8, each dummy structure 4 has a thickness equal to a thickness of the first signal wires 11. Therefore, the layer segment difference caused by the first signal wires 11 can be leveled.

In some embodiments, referring to FIG. 8, each dummy structure 4 is made of an insulating material.

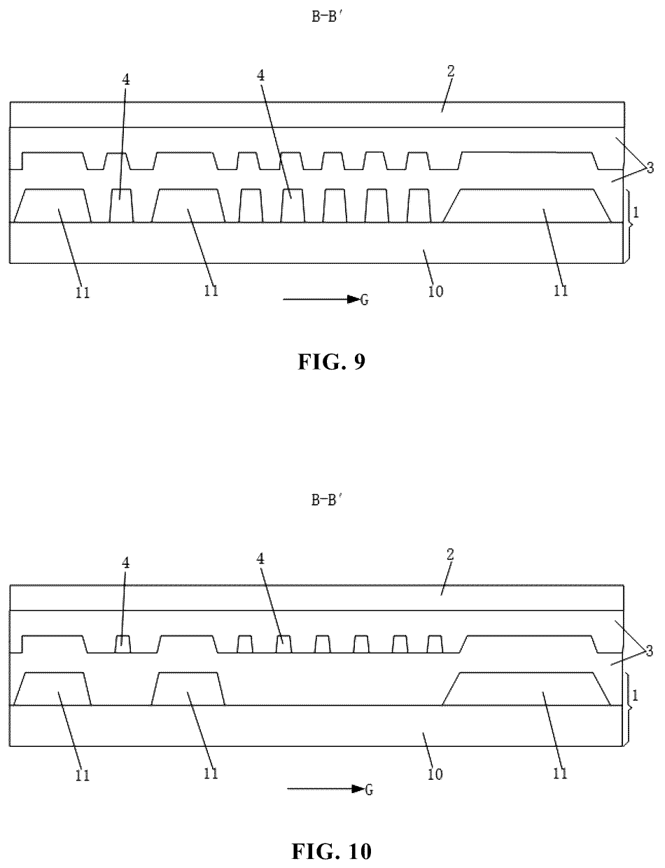

In some embodiments, referring to FIG. 9, a sectional view illustrating yet another structure of the display substrate in FIG. 5 taken along line BB′ is shown. The auxiliary leveling structure further includes a plurality of dummy structures 4 in the same layer as the first signal wires 11 and distributed at least in a region of an orthographic projection of a corresponding first electrode 2 on the base 10. Orthographic projections of the dummy structures 4 on the base 10 are not overlapped with the orthographic projections of the first signal wires 11 on the base 10, and adjacent first signal wires 11, and each dummy structure 4 and an adjacent first signal wire 11, are equally spaced.

In the display substrate of FIG. 9, each dummy structure 4 has a thickness equal to a thickness of the first signal wires 11.

In some embodiments, referring to FIG. 10, a sectional view illustrating yet another structure of the display substrate in FIG. 5 taken along line BB′ is shown. The auxiliary leveling structure further includes a plurality of dummy structures 4 between any two adjacent planarization layers 3 and distributed at least in a region of an orthographic projection of a corresponding first electrode 2 on the base 10. Orthographic projections of the dummy structures 4 on the base 10 are not overlapped with the orthographic projections of the first signal wires 11 on the base 10, and the orthographic projections of adjacent first signal wires 11 on the base 10, the orthographic projections of each dummy structure 4 and an adjacent first signal wire 11 on the base 10, and the orthographic projections of adjacent dummy structures 4 on the base 10, are equally spaced.

In the display substrate of FIG. 10, each dummy structure 4 has a thickness less than or equal to a thickness of the first signal wires 11.

In the display substrate structure shown in FIGS. 9 and 10 in this embodiment, dummy structures 4 are provided in the layer where the first signal wires 11 are located or between two adjacent planarization layers 3, and each dummy structure 4 and an adjacent first signal wire 11, adjacent first signal wires 11, and adjacent dummy structures 4 are equally spaced, so that the non-uniform layer segment difference caused by the first signal wires 11 becomes uniform by filling with the dummy structures 4, and then, by providing the planarization layers 3 on the dummy structures 4, the layer segment difference caused by the first signal wires 11 can be leveled, so that a surface, close to the first electrodes 2, of one of the planarization layers 3 closest to the first electrodes 2 is planar, and therefore, the layer of the first electrodes 2 formed thereon are made flat.

In some embodiments, in the display substrate structure of FIG. 9, one planarization layer 3 may be provided; and in the display substrate structure of FIG. 10, two planarization layers 3 may be provided. The layer flatness of the first electrodes 2 can be achieved, although the number of planarization layers 3 in the display substrate structures of FIGS. 7 to 10 is smaller than the number of planarization layers 3 in the display substrate of FIG. 6, or the planarization layer 3 in the display substrate structures of FIGS. 7 to 10 has a thickness less than the planarization layer 3 in the display substrate of FIG. 6.

In some embodiments, the plurality of first signal wires 11 are parallel to each other; the orthographic projections of adjacent first signal wires 11 on the base 10, the orthographic projections of each dummy structure 4 and an adjacent first signal wire 11 on the base 10, and the orthographic projections of adjacent dummy structures 4 on the base 10, are spaced by a distance less than or equal to a minimum line width of the first signal wires 11; and a width of each dummy structure 4 in an arrangement direction G of the plurality of first signal wires 11 is less than or equal to the minimum line width of the first signal wires 11. With such arrangement, the width of the first signal wire 11, the width of the dummy structure 4, the distance between adjacent first signal wires 11, the distance between each dummy structure 4 and an adjacent first signal wire 11, and the distance between adjacent dummy structures 4, are substantially the same, so that the surface of the pixel driver circuit 1 in direct contact with the first electrodes 2 tends to be flat or is a plane, and therefore, the layer flatness of the first electrodes 2 can be achieved.

In this embodiment, in the display substrate structure scheme of FIGS. 9 and 10, each dummy structure 4 is made of an insulating material or a conductive material.

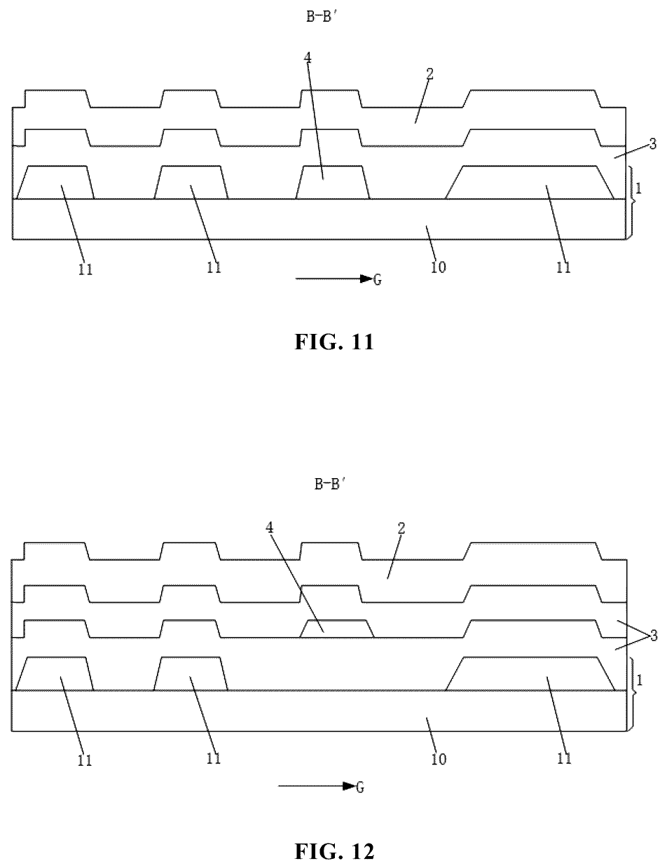

In some embodiments, referring to FIG. 11, a sectional view illustrating yet another structure of the display substrate in FIG. 5 taken along line BB′ is shown. The auxiliary leveling structure includes a plurality of dummy structures 4, and a plurality of planarization layers 3 having orthographic projections on the base 10 covering an orthographic projection of the pixel driver circuit 1 on the base 10. The plurality of dummy structures 4 are in the same layer as the first signal wires 11; and the plurality of dummy structures 4 are distributed at least in a region of an orthographic projection of a corresponding first electrode 2 on the base 10. Orthographic projections of the dummy structures 4 on the base 10 are not overlapped with the orthographic projections of the first signal wires 11 on the base 10, and adjacent first signal wires 11, and each dummy structure 4 and an adjacent first signal wire 11, are equally spaced. The plurality of planarization layers 3 are sequentially stacked on a side of the first signal wires 11 away from the base 10, and a surface, close to the first electrodes 2, of one of the planarization layers 3 closest to the first electrodes 2 is a uniformly concaved surface.

In the display substrate of FIG. 11, each dummy structure 4 has a thickness equal to a thickness of the first signal wires 11.

In some embodiments, referring to FIG. 12, a sectional view illustrating yet another structure of the display substrate in FIG. 5 taken along line BB′ is shown. The auxiliary leveling structure includes a plurality of dummy structures 4, and a plurality of planarization layers 3 having orthographic projections on the base 10 covering an orthographic projection of the pixel driver circuit 1 on the base 10. The plurality of dummy structures 4 are located between any two adjacent planarization layers 3; and the plurality of dummy structures 4 are distributed at least in a region of an orthographic projection of a corresponding first electrode 2 on the base 10. Orthographic projections of the dummy structures 4 on the base 10 are not overlapped with the orthographic projections of the first signal wires 11 on the base 10, and the orthographic projections of adjacent first signal wires 11 on the base 10, the orthographic projections of each dummy structure 4 and an adjacent first signal wire 11 on the base 10, and the orthographic projections of adjacent dummy structures 4 on the base 10, are equally spaced. The plurality of planarization layers 3 are sequentially stacked on a side of the first signal wires 11 away from the base 10, and a surface, close to the first electrodes 2, of one of the planarization layers 3 closest to the first electrodes 2 is a uniformly concaved surface.

In the display substrate of FIG. 12, each dummy structure 4 has a thickness less than or equal to a thickness of the first signal wires 11.

In some embodiments, referring to FIGS. 11 and 12, each first electrode 2 is a uniformly concaved layer. The uniformly concaved first electrode 2 can uniformly scatter light irradiated thereon. For example, where the first electrode 2 is made of an opaque reflective material (e.g., corresponding to a top-emitting OLED element), the first electrode 2 can uniformly reflect and scatter light irradiated thereon; and where the first electrode 2 is made of a transparent material (e.g., corresponding to a bottom-emitting OLED element), the first electrode 2 can uniformly transmit and scatter light irradiated thereon, thereby alleviating or eliminating the problem of asymmetrical viewing angle of the display panel employing the display substrate.

In this embodiment, referring to FIGS. 11 and 12, by arranging the plurality of dummy structures 4 and the plurality of planarization layers 3, and making a surface, close to the first electrodes 2, of one of the planarization layers 3 closest to the first electrodes 2 a uniformly concaved surface, the first electrode 2 forms a uniformly concaved layer. In other words, the layer of the first electrode 2 tends to be flat, so that the first electrode 2 can uniformly scatter light irradiated thereon, thereby finally alleviating or eliminating the problem of asymmetrical viewing angle of the display panel employing the display substrate.

In some embodiments, referring to FIGS. 11 and 12, the orthographic projections of adjacent first signal wires 11 on the base 10, the orthographic projections of each dummy structure 4 and an adjacent first signal wire 11 on the base 10, and the orthographic projections of adjacent dummy structures 4 on the base 10, are spaced by a distance equal to an average line width of the plurality of first signal wires 11, respectively; and a width of each dummy structure 4 in an arrangement direction G of the plurality of first signal wires 11 is equal to the average line width of the plurality of first signal wires 11. With such arrangement, the uniform concaves and convexes on the layer of the first electrode 2 can have a radial dimension in the arrangement direction G of the plurality of first signal wires 11 approximately equal to the average line width of the plurality of first signal wires 11. In other words, the uniform concaves and convexes on the layer of the first electrode 2 each have a very small radial dimension, making the layer of the first electrode 2 nearly planar, so that the first electrode 2 can scatter light irradiated thereon very uniformly, thereby alleviating or eliminating the problem of asymmetrical viewing angle of the display panel employing the display substrate.

In some embodiments, referring to FIGS. 9 to 12, one of the planarization layers 3 closest to the first signal wires 11 has a larger thickness than a thickness of the first signal wires 11.

In the display substrate of FIGS. 9 to 12, each dummy structure 4 is made of an insulating material or a conductive material; and the conductive material includes the same conductive material as the first signal wires 11.

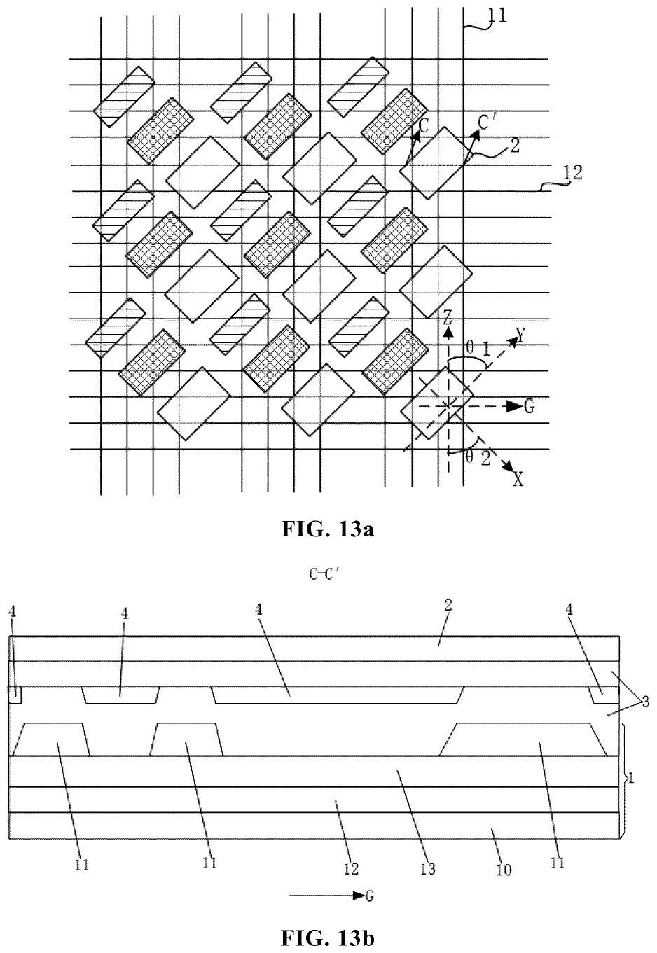

In some embodiments, referring to FIGS. 13a and 13b, where FIG. 13a is a top view illustrating another structure of a display substrate according to an embodiment of the present disclosure; and FIG. 13b is a sectional view illustrating a structure of the display substrate in FIG. 13a taken along line CC′; the pixel driver circuit 1 further includes a plurality of second signal wires 12 in a same layer on the base 10; the plurality of second signal wires 12 have the same extending direction; the extending direction of the second signal wires 12 forms acute angles greater than 0° and smaller than 90° with the length direction Y and the width direction X of the strip, respectively; and the second signal wires 12 are located on a side of the first signal wires 11 close to the base 11; and an insulation layer 13 is further provided between the second signal wires 12 and the first signal wires 11.

In some embodiments, the extending direction of the second signal wires 12 is the same as the arrangement direction of the plurality of first signal wires 11; the plurality of second signal wires 12 are parallel to each other; and an arrangement direction of the plurality of second signal wires 12 is the same as the extending direction Z of the first signal wires 11.

In some embodiments, the extending direction of the second signal wires 12 forms angles of 40° to 50° with the length direction Y and the width direction X of the strip, respectively.

In some embodiments, the extending direction of the second signal wires 12 forms an angle of 45° with the length direction Y and the width direction X of the strip, respectively.

In this embodiment, by forming acute angles greater than 0° and smaller than 90° between the extending direction of the second signal wires 12 and the length direction Y and the width direction X of the strip, respectively, especially by forming angles of 45° between the extending direction of the second signal wires 12 and the length direction Y and the width direction X of the strip, respectively, an aperture ratio of the display panel employing the display substrate can be increased on the one hand, and on the other hand, a visual effect with an oblique step feeling of the display panel employing the display substrate can be enhanced.

In some embodiments, the second signal wires 12 include gate lines or data lines or power lines. Where the first signal wires 11 are data lines and/or power lines, the second signal wires 12 are gate lines and/or other signal wires parallel to, and disposed in the same layer with, gate lines. Where the first signal wires 11 are gate lines and/or other signal wires parallel to, and disposed in the same layer with, gate lines, the second signal wires 12 are data lines and/or power lines.

In some embodiments, an auxiliary leveling structure as described in any of the above embodiments may also be provided between the second signal wires 12 and the first electrode 2, so as to facilitate leveling the surface segment difference of the pixel driver circuit 1 caused by the second signal wires 12, make the layer of the first electrodes 2 formed on the pixel driver circuit 1 flat, and finally alleviate or eliminate the problem of asymmetrical viewing angle of the display panel employing the display substrate.

In this embodiment, the first signal wires 11 closest to the first electrode 2 in the pixel driver circuit 1 contribute more to the surface segment difference of the pixel driver circuit 1 than the second signal wires 12, and therefore, the auxiliary leveling structure is preferably provided between the first signal wires 11 and the first electrode 2.

In this embodiment, referring to FIGS. 6 to 13b, the pixel driver circuit 1 is disposed on the base 10, and the circuit structure of the pixel driver circuit 1 is not shown in the figures.

Based on the above structure of the display substrate, an embodiment of the present disclosure further provides a method for manufacturing the display substrate, including: manufacturing a pixel driver circuit; and manufacturing a plurality of first electrodes on the pixel driver circuit; where manufacturing the pixel driver circuit includes manufacturing a plurality of first signal wires on a base; where the plurality of first signal wires have the same extending direction; orthographic projections of the first signal wires on the base are partially overlapped with orthographic projections of the first electrodes on the base; the first electrodes each have a strip shape, and the plurality of first electrodes are arranged in an array along a length direction and a width direction of the strip shape; the extending direction of the first signal wires forms acute angles greater than 0° and smaller than 90° with the length direction and the width direction of the strip, respectively; and after manufacturing the pixel driver circuit and before manufacturing the first electrodes, the method further includes: manufacturing an auxiliary leveling structure, where an orthographic projection of the auxiliary leveling structure on the base covers at least the orthographic projections of the first electrodes on the base.

The plurality of first signal wires are manufactured on the base through a patterning process (including film deposition, exposure, development, etching, and the like). The plurality of first electrodes are manufactured on the pixel driver circuit through a patterning process (including film deposition exposure, development, etching, and the like).

In some embodiments, manufacturing the auxiliary leveling structure includes: manufacturing a plurality of planarization layers sequentially through a coating process.

In some embodiments, manufacturing the auxiliary leveling structure further includes: manufacturing a dummy structure through a patterning process. Where the dummy structure is made of an insulating material, the dummy structure is manufactured by film deposition (chemical vapor deposition), exposure, development, dry etching or other processes. Where the dummy structure is made of a conductive material, the dummy structure is manufactured by film deposition, exposure, development, wet etching or other processes.

In some embodiments, where the dummy structure is formed between two adjacent planarization layers, the dummy structure is manufactured after one of the planarization layers is manufactured and before the other of the planarization layers is manufactured in manufacturing of any two adjacent planarization layers.

In some embodiments, where the dummy structure and the first signal wires are made of the same material and located in the same layer, the dummy structure and the first signal wires are manufactured in a single patterning process (including film deposition, exposure, development, etching, and the like).

In some embodiments, where the dummy structure and the first signal wires are made of different materials and located in the same layer, the first signal wires and the dummy structure are sequentially manufactured in a single patterning process. If the dummy structure is made of an inorganic insulating material, the dummy structure is manufactured through film deposition, exposure, development, dry etching and other steps. The first signal wires are made of a conductive material, and manufactured through film deposition, exposure, development, wet etching and other steps.

In the display substrate provided in the embodiments of the present disclosure, by providing the auxiliary leveling structure between the layer where the first signal wires are located and the layer where the first electrodes are located, and making the orthographic projection of the auxiliary leveling structure on the base cover at least the orthographic projections of the first electrodes on the base, a surface layer of the pixel driver circuit corresponding to the region where the first electrodes are located can be filled and leveled, thereby making the layer of the first electrodes, which is formed in the region of the leveled surface layer, be flat or tend to be flat. Therefore, the problem of asymmetrical viewing angle of the display panel employing the display substrate can be alleviated or eliminated, and the display effect of the display panel employing the display substrate can be improved.

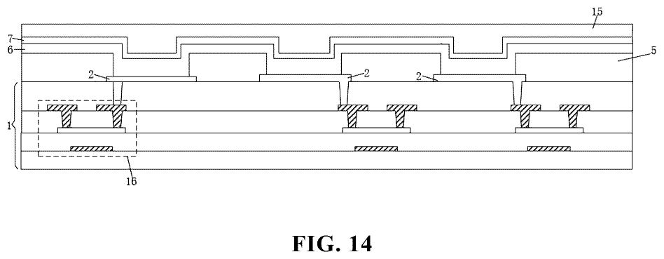

An embodiment of the present disclosure further provides a display panel which, referring to FIG. 14, a sectional view illustrating a structure of a display panel according to an embodiment of the present disclosure is shown. The display panel includes the display substrate in any of the above embodiments.

In some embodiments, the display panel further includes a pixel defining layer 5, an emission functional layer 6, and a second electrode 7. The pixel defining layer 5, the emission functional layer 6 and the second electrode 7 are sequentially stacked on a side of the first electrodes 2 in the display substrate away from the pixel driver circuit 1; and the pixel defining layer 5 is provided with a plurality of openings from which the first electrodes 2 are partially exposed, and orthographic projections of the emission functional layer 6 and the second electrode 7 on the pixel driver circuit 1 cover at least orthographic projections of the openings on the pixel driver circuit 1.

In some embodiments, the display panel further includes an encapsulation layer 15 on a side of the second electrode 7 away from the display substrate and configured to encapsulate the light-emitting device formed by the first electrodes 2, the emission functional layer 6, and the second electrode 7 in a stack.

In some embodiments, the pixel driver circuit 1 is provided with a driver circuit including a driving transistor 16 with a drain connected to a corresponding first electrode 2 to provide a driving current for the first electrode 2.

By adopting the display substrate in any of the above embodiments, the display panel provided in the embodiment of the present disclosure can alleviate or eliminate the problem of asymmetrical viewing angle of the display panel employing the display substrate, and improve the display effect of the display panel.

An embodiment of the present disclosure further provides a display apparatus including the display panel according to any one of the above embodiments.

By adopting the display panel in any of the above embodiments, the display apparatus provided in the embodiment of the present disclosure can alleviate or eliminate the problem of asymmetrical viewing angle of the display apparatus employing the display substrate, and the display effect of the display apparatus can be improved.

The display apparatus may include: an OLED panel, an OLED television, an LED panel, an LED television, a Mini LED panel, a Mini LED television, a Micro LED panel, a Micro LED television, a mobile phone, a tablet, a laptop, a monitor, a digital album, a navigator or any other product or component having a display function.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A display substrate, comprising a pixel driver circuit and a plurality of first electrodes on the pixel driver circuit, wherein
the pixel driver circuit comprises a base, and a plurality of first signal wires in a same layer on the base; the plurality of first signal wires have the same extending direction;
the first electrodes and the first signal wires are in different layers;
orthographic projections of the first signal wires on the base are partially overlapped with orthographic projections of the first electrodes on the base;
the first electrodes each have a strip shape, and the plurality of first electrodes are arranged in an array along a length direction and a width direction of the strip shape;
the extending direction of the first signal wires forms acute angles greater than 0° and smaller than 90° with the length direction and the width direction of the strip, respectively;
the display substrate further comprises an auxiliary leveling structure on a side of the first signal wires away from the base and a side of the first electrodes close to the base, and an orthographic projection of the auxiliary leveling structure on the base covers at least the orthographic projections of the first electrodes on the base; and
the auxiliary leveling structure enables a layer of the first electrodes flat.

2. The display substrate according to claim 1, wherein the auxiliary leveling structure comprises a plurality of planarization layers having orthographic projections on the base covering an orthographic projection of the pixel driver circuit on the base;
the plurality of planarization layers are sequentially stacked on a side of the first signal wires away from the base, and a surface, close to the first electrodes, of one of the planarization layers closest to the first electrodes is planar; and
each first electrode is a planar layer.

3. (canceled)

4. The display substrate according to claim 2, wherein the auxiliary leveling structure further comprises a dummy structure between any two adjacent planarization layers or in the same layer as the first signal wires and distributed at least in a region of an orthographic projection of a corresponding first electrode on the base; and
an orthographic projection of the dummy structure on the base is not overlapped with the orthographic projections of the first signal wires on the base, and forms a complementary pattern with the orthographic projections of the first signal wires on the base.

5. (canceled)

6. The display substrate according to claim 2, wherein the auxiliary leveling structure further comprises a plurality of dummy structures in the same layer as the first signal wires or between any two adjacent planarization layers and distributed at least in a region of an orthographic projection of a corresponding first electrode on the base; and
orthographic projections of the dummy structures on the base are not overlapped with the orthographic projections of the first signal wires on the base, and the orthographic projections of adjacent first signal wires on the base, the orthographic projections of each dummy structure and an adjacent first signal wire on the base, and the orthographic projections of adjacent dummy structures on the base, are equally spaced.

7. The display substrate according to claim 6, wherein the plurality of first signal wires are parallel to each other;
the orthographic projections of adjacent first signal wires on the base, the orthographic projections of each dummy structure and an adjacent first signal wire on the base, and the orthographic projections of adjacent dummy structures on the base, are spaced by a distance less than or equal to a minimum line width of the first signal wires; and
a width of each dummy structure in an arrangement direction of the plurality of first signal wires is less than or equal to the minimum line width of the first signal wires.

8. (canceled)

9. The display substrate according to claim 1, wherein the auxiliary leveling structure comprises a plurality of dummy structures and a plurality of planarization layers, and orthographic projections of the plurality of planarization layers on the base cover an orthographic projection of the pixel driver circuit on the base;
the plurality of dummy structures are in the same layer as the first signal wires or between any two adjacent planarization layers; and the plurality of dummy structures are distributed at least in a region of an orthographic projection of a corresponding first electrode on the base;
orthographic projections of the dummy structures on the base are not overlapped with the orthographic projections of the first signal wires on the base, and the orthographic projections of adjacent first signal wires on the base, the orthographic projections of each dummy structure and an adjacent first signal wire on the base, and the orthographic projections of adjacent dummy structures on the base, are equally spaced; and
the plurality of planarization layers are sequentially stacked on a side of the first signal wires away from the base, and a surface, close to the first electrodes, of one of the planarization layers closest to the first electrodes is a uniformly concaved surface.

10. The display substrate according to claim 9, wherein each first electrode is a uniformly concaved layer.

11. The display substrate according to claim 10, wherein the orthographic projections of adjacent first signal wires on the base, the orthographic projections of each dummy structure and an adjacent first signal wire on the base, and the orthographic projections of adjacent dummy structures on the base, are spaced by a distance equal to an average line width of the plurality of first signal wires, respectively; and
a width of each dummy structure in an arrangement direction of the plurality of first signal wires is equal to the average line width of the plurality of first signal wires.

12. The display substrate according to claim 2, wherein one of the planarization layers closest to the first signal wires has a larger thickness than a thickness of the first signal wires.

13. The display substrate according to claim 6, wherein the plurality of dummy structures are between any two adjacent planarization layers, and each dummy structure has a thickness less than or equal to a thickness of the first signal wires.

14. The display substrate according to claim 6, wherein the plurality of dummy structures are in the same layer as the first signal wires, and each dummy structure has a thickness equal to a thickness of the first signal wires.

15. The display substrate according to claim 6, wherein each dummy structure is made of an insulating material or a conductive material; and
the conductive material comprises the same conductive material as the first signal wires.

16. The display substrate according to claim 4, wherein the dummy structure is made of an insulating material.

17. The display substrate according to claim 1, wherein the pixel driver circuit further comprises a plurality of second signal wires in a same layer on the base;
the plurality of second signal wires have the same extending direction;
the extending direction of the second signal wires forms acute angles greater than 0° and smaller than 90° with a length direction and a width direction of the strip, respectively;
the second signal wires are on a side of the first signal wires close to the base; and
an insulation layer is further provided between the second signal wires and the first signal wires.

18. The display substrate according to claim 17, wherein the extending direction of the first signal wires forms angles of 40° to 50° with the length direction and the width direction of the strip, respectively; and
the extending direction of the second signal wires forms angles of 40° to 50° with the length direction and the width direction of the strip, respectively.

19. The display substrate according to claim 1, wherein the first electrodes each have a shape comprising any one of rectangle, diamond, ellipse, or trapezoid.

20. The display substrate according to claim 18, wherein the first signal wires comprise data lines or power lines or gate lines; and
the second signal wires comprise gate lines or data lines or power lines.

21. The display substrate according to claim 15, wherein each dummy structure is made of a conductive material and connected to a first potential signal or a second potential signal;
the first potential signal is greater than the second potential signal; the second potential signal is greater than or equal to a ground potential; and
the first potential signal comprises a potential of a power line.

22. (canceled)

23. A display panel, comprising the display substrate according to claim 1, and further comprising a pixel defining layer, an emission functional layer, and a second electrode; wherein
the pixel defining layer, the emission functional layer and the second electrode are sequentially stacked on a side of the first electrodes in the display substrate away from the pixel driver circuit; and
the pixel defining layer is provided with a plurality of openings from which the first electrodes are partially exposed, and orthographic projections of the emission functional layer and the second electrode on the pixel driver circuit cover at least orthographic projections of the openings on the pixel driver circuit.

24. A display apparatus, comprising the display panel according to claim 23.

25-30. (canceled)
